(19) United States
(12) Patent Application Publication
(10) Pub. No.: US 2010/0269011 A1
(43) Pub. Date: Oct. 21, 2010

(54) APPARATUS AND METHOD FOR DECODING LOW DENSITY PARITY CHECK CODE USING PROTOTYPE MATRIX

(75) Inventors: Jong-Ee Oh, Daejeon (KR); Yuro Lee, Daejeon (KR); Jungbo Son, Daejeon (KR); Sok-Kyu Lee, Daejeon (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/747,694

(22) PCT Filed: Jun. 4, 2008
(86) PCT No.: PCT/KR2008/003124

§ 371 Date: Jun. 11, 2010

(30) Foreign Application Priority Data
Dec. 12, 2007 (KR) 1020070129185

(51) Int. Cl. H03M 13/05; G06F 11/10

(52) U.S. Cl. 714/752; 714/E11.032

(57) ABSTRACT

Provided is an apparatus and method for decoding a low density parity check (LDPC) code using a prototype matrix. The apparatus includes: a bit input unit for receiving a log likelihood ratio (LLR) value for an input bit; a check matrix processing unit for sequentially processing a parity check matrix for the received LLR value using a prototype parity check matrix through partial-parallel processing; and a bit processing unit for restoring the input bit by determining a bit level from the partial-parallel processed parity check matrix value.

### TECHNICAL FIELD

The present invention relates to an apparatus and method for decoding a low density parity check (LDPC) code using a prototype matrix; and, more particularly, to an apparatus and method for decoding a LDPC code using a prototype matrix, which partial-parallel process a parity check matrix using a prototype parity check matrix in order to decode the LDPC code at a high speed while reducing complexity.

This work was supported by the IT R&D program of MIC/IITA [2006-S-002-02, “IMT-Advanced Radio Transmission Technology with Low Mobility”].

### BACKGROUND ART

In a wired/wireless communication system, a transmitted signal experiences noise, interference, and fading on a transmission channel. Therefore, a receiving end may have difficulty to demodulate the transmitted signal.

An error correction code is one of representative methods for reducing an error generation rate which increases in proportion to a transmission rate. Lately, almost wireless communication systems adopt the error correction code. Particularly, a low density parity check (LDPC) code has been receiving attention as an error correction code for a next generation high capacity wireless communication system because the LDPC code provides excellent error correction performance and enables a high speed decoder to be embodied with low complexity.

A LDPC code was introduced by Gallager. The LDPC code is defined as a matrix constituted of many 0s and few is as elements.

The LDPC code is classified into a regular LDPC code and an irregular LDPC code. The regular LDPC code is a LDPC code introduced by Gallager. In a parity check matrix of the regular LDPC code, all rows have the same number of is and all columns also have the same number of 1s. On the contrary, a parity check matrix of the irregular LDPC code includes rows having the different number of 1s and columns having the different number of 1s. In general, it was widely known that the error correction performance of the irregular LDPC code is better than that of the regular LDPC code.

Meanwhile, a Quasi-cyclic LDPC code was introduced by Fossorier. In the Quasi-cyclic LDPC code, the elements of a parity check matrix are expressed as cyclic-shifted identity matrices and 0 matrices instead of 0s and 1s.

As a method for decoding the LDPC code, a serial or partial parallel decoding method and a parallel decoding method were introduced.

Since the serial or partial parallel decoding method repeatedly uses the small number of common blocks for processing a variable node and a check node, it is possible to advantageously reduce a hardware size. However, the serial or partial parallel decoding method cannot support high speed decoding.

On the contrary, the parallel decoding method can advantageously support high speed decoding by exchanging information in parallel through variable node processing blocks and check node processing blocks, which are optimized to each parity check matrix. However, the parallel decoding method also has a disadvantage of a large hardware size. That is, the larger the hardware size increases, the more various code rates are supported.

Meanwhile, a wired/wireless communication system must use an error correction code having a variable information length and a variable code rate in order to adaptively use different modulation and coding schemes (MCS) according to a channel state. Therefore, various decoding methods for supporting various MCS levels were introduced, for example, a method for employing independent decoders according to each of information lengths and code rates or a method for applying an information shortening scheme or a puncturing scheme although one hardware is used.

However, the former method has a shortcoming of a large hardware size, and the later method has a disadvantage that error correction performance of a LDPC code significantly deteriorates because one of the information shortening scheme and the parity puncturing scheme is randomly selected and used.

As described above, the parallel decoding method is better for a high speed wireless communication system that supports a fast processing speed of several Giga bits per second. Lately, it has been required to use a LDPC code having a variable information length and a variable code rate having excellent error correction performance in order to effectively apply an adaptive modulation and demodulation scheme. It has been also required that the complexity of encoding and decoding of the LDPC code must be low.

However, it is not easy to process entire LDPC codes in parallel due to complicated random connection of variable nodes and check nodes. Also, variable nodes and check nodes used for parallel processing must be stored in a memory. Therefore, the memory space is unnecessarily used.

### DISCLOSURE OF INVENTION

### Technical Problem

An embodiment of the present invention is directed to providing an apparatus and method for decoding a LDPC code using a prototype matrix, which partial-parallel process a parity check matrix using a prototype parity check matrix in order to decode the LDPC code at a high speed while reducing complexity.

Another embodiment of the present invention is directed to providing an apparatus and method for decoding a LDPC code using a prototype matrix, which partial-parallel process a parity check matrix using a prototype parity check matrix to decode an input bit through the LDPC code.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Technical Solution

In accordance with an aspect of the present invention, there is provided an apparatus for decoding a low density parity check (LDPC) code using a prototype parity check matrix. The apparatus includes: a bit input unit for receiving a log likelihood ratio (LLR) value for an input bit; a check matrix processing unit for sequentially processing a parity check matrix for the received LLR value using a prototype parity check matrix through partial-parallel processing; and a bit processing unit for restoring the input bit by determining a bit level from the partial-parallel processed parity check matrix value.

In accordance with another aspect of the present invention, there is provided a method for decoding a low density parity check (LDPC) code, including: receiving a log likelihood ratio (LLR) value for an input bit; sequentially processing a parity check matrix for the received LLR value using a prototype parity check matrix through partial-parallel processing; and restoring the input bit by determining a bit level from the partial-parallel processed parity check matrix value.

### ADVANTAGEOUS EFFECTS

As described above, the parity check matrix is sequentially processed through partial parallel processing using a prototype parity check matrix for decoding an input bit using the LDPC code. Therefore, it is possible to process the parity check matrix at a high speed while reducing complexity compared to the conventional parallel decoding method.

Also, it is possible to reduce a memory area for storing variable nodes and check nodes of the parity check matrix, and it is possible to embody a high speed decoding apparatus through simple-cyclic shifting.

### BRIEF DESCRIPTION OF THE DRAWINGS

FIG. 1 is a diagram illustrating a parity check matrix of a Quasi-Cyclic Low Density Parity Check (QC-LDPC) code where the present invention is applied.

FIG. 2 is a diagram illustrating a factor graph of a parity check matrix of FIG. 1.

FIGS. 3 and 4 are diagrams for describing a method for parallel processing a parity check matrix according to the related art.

FIG. 5 is a diagram illustrating an apparatus for decoding a low density parity check (LDPC) code using a prototype parity matrix in accordance with an embodiment of the present invention.

FIG. 6 is a diagram illustrating edges connected to a first check node among edges connecting variable nodes and check nodes shown in FIG. 2.

FIGS. 7 and 8 are diagrams illustrating a factor graph of a parity check matrix in accordance with an embodiment of the present invention.

FIG. 9 is a diagram illustrating a method for sequentially processing a parity check matrix of FIG. 1 using a prototype parity check matrix in accordance with an embodiment of the present invention.

FIG. 10 is a diagram illustrating a parity check matrix of irregular Quasi Cyclic Low Density Parity Check (QC-LDPC) code where the present invention is applied to.

FIGS. 11 to 13 are diagrams illustrating a method for partial parallel processing a parity check matrix using a prototype parity check matrix in accordance with an embodiment of the present invention.

FIG. 14 is a diagram illustrating another parity check matrix of an irregular QC-LDPC code where the present invention is applied.

FIG. 15 is a flowchart illustrating a method for decoding a LDPC code using a prototype matrix in accordance with an embodiment of the present invention.

### BEST MODE FOR CARRYING OUT THE INVENTION

The advantages, features and aspects of the invention will become apparent from the following description of the embodiments with reference to the accompanying drawings, which is set forth hereinafter. Therefore, those skilled in the field of this art of the present invention can embody the technological concept and scope of the invention easily. In addition, if it is considered that detailed description on a related art may obscure the points of the present invention, the detailed description will not be provided herein. The preferred embodiments of the present invention will be described in detail hereinafter with reference to the attached drawings.

Throughout the specification, the present invention will be described with a fixed size of a sub-matrix, the fixed number of sub-matrices, and fixed degree distribution of a parity check matrix. However, it is obvious to those skilled in the art that the present invention also relates to a method for modifying a length of an n×n sub-matrix, a method for modifying the number of sub-matrix, and a method for using a parity check matrix modified according to variation of degree distribution of the parity check matrix.

Eq. 1 show typical 5×5 cyclic permutation matrices.

$${S}_{0} = [ \begin{matrix}1 & 0 & 0 & 0 & 0 \\ 0 & 1 & 0 & 0 & 0 \\ 0 & 0 & 1 & 0 & 0 \\ 0 & 0 & 0 & 1 & 0 \\ 0 & 0 & 0 & 0 & 1\end{matrix} ] \cdot {S}_{1} = [ \begin{matrix}0 & 1 & 0 & 0 & 0 \\ 0 & 0 & 1 & 0 & 0 \\ 0 & 0 & 0 & 1 & 0 \\ 0 & 0 & 0 & 0 & 1 \\ 1 & 0 & 0 & 0 & 0\end{matrix} ] \cdot {S}_{3} = [ \begin{matrix}0 & 0 & 0 & 1 & 0 \\ 0 & 0 & 0 & 0 & 1 \\ 1 & 0 & 0 & 0 & 0 \\ 0 & 1 & 0 & 0 & 0 \\ 0 & 0 & 1 & 0 & 0\end{matrix} ] \qquad Eq . 1$$

In Eq. 1, Sᵢ denotes a 5×5 cyclic permutation matrix (sub-matrix).

As shown in Eq. 1, the sub-matrix Sᵢ is a matrix obtained by cyclic-shifting columns of a unitary matrix by i to the right.

Hereinafter, a parity check matrix, which is constituted of a regular LDPC code formed of 5×5 sub-matrices, an irregular LDPC formed of 7×7 sub-matrices, and an irregular LDPC code formed of 38×38 of sub-matrices, is exemplary used to described the present invention. The sub-matrix includes a cyclic shifted n×n unitary matrix (that is, a cyclic permutation matrix), or an n×n 0 matrix.

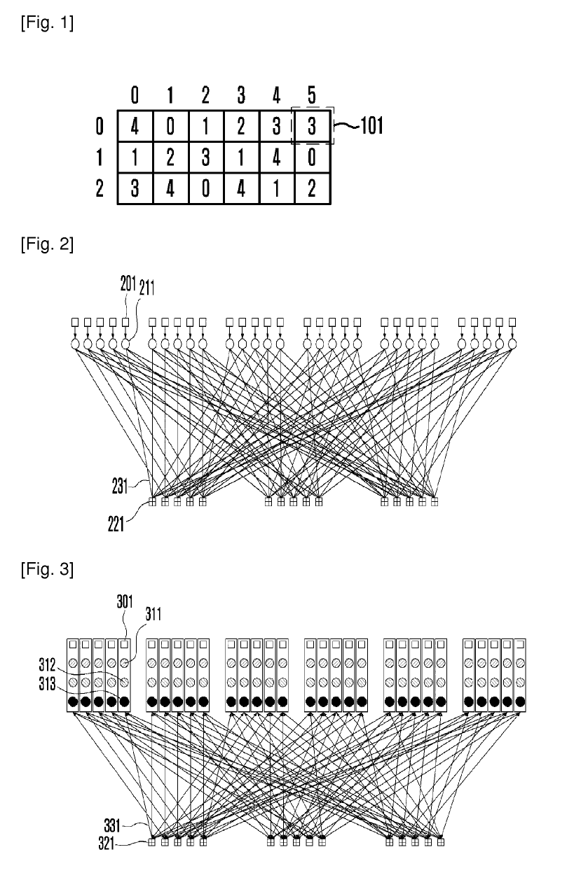

FIG. 1 is a diagram illustrating a parity check matrix of a QC-LDPC code where the present invention is applied.

As shown in FIG. 1, a square 101 denotes a 5×5 unitary matrix (sub-matrix) and a value in the square 101 is the number of columns cyclically shifted to the right. For example, the square 101 with “3” means S₃ shown in Eq. 1.

Therefore, in the parity check matrix of the QC-LDPC code shown in FIG. 1, a 5×5 sub-matrix is formed of three rows and six columns. That is, the parity check matrix of a QC-LDPC code is constituted of 15 rows and 30 columns. A value of adding “1” to each column is constant as 6, and a value of adding “1” to each row is constant as 3.

FIG. 2 is a diagram illustrating a factor graph of a parity check matrix of FIG. 1.

As shown in FIG. 2, the factor grape of the parity check matrix of FIG. 1 includes squares 201, circles 211, squares 221 with a cross marked, and edges 231. The squares 201 mean a log likelihood ratio (LLR) inputted to a LDPC code decoding apparatus according to an embodiment of the present invention. Hereinafter, the square 201 refers to a LLR. The circles 211 denote a variable node. The squares 221 with the cross marked denote a check node.

The variable nodes 211 and the check nodes 221 are connected through edges 231 at parts where an element is 1 in the parity check matrix of FIG. 1. The factor graph includes thirty variable nodes 211 like the number of columns in the parity check matrix, and thirty check nodes 221 like the number of rows in the parity check matrix. That is, six row elements of the parity check matrix of FIG. 1 are equivalent to the variable nodes 211 of FIG. 2, and three column elements of the parity check matrix of FIG. 2 are equivalent to the check nodes 221 of FIG. 2.

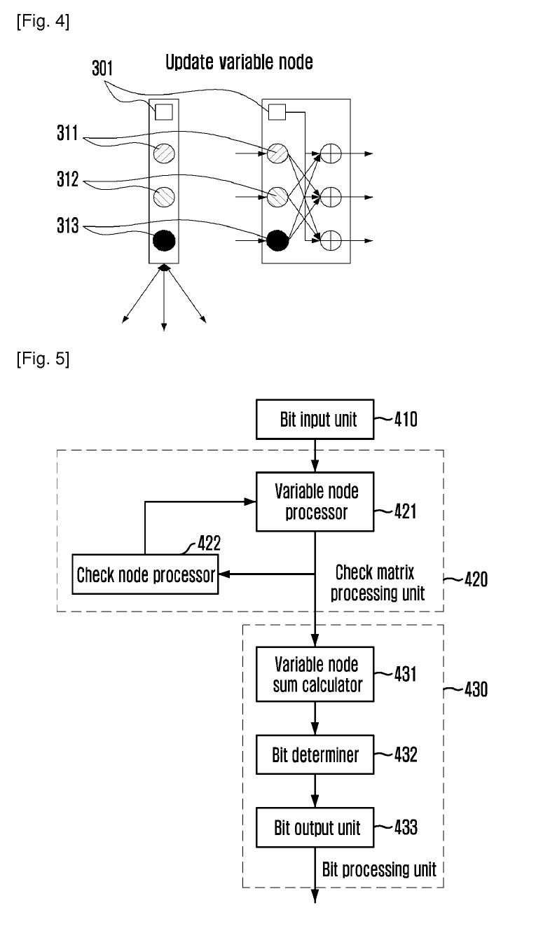

Hereinafter, a method for parallel processing a parity check matrix according to the related art will be described with reference to FIGS. 3 and 4.

FIGS. 3 and 4 are diagrams for describing a method for parallel processing a parity check matrix according to the related art.

For convenience, the variable node 211 of FIG. 2 will be described as three variable nodes 311 to 313, hereinafter.

In the parallel processing method according to the related art, thirty LLR values 301 are inputted, and thirty LLR values are stored in each of memories.

Then, the stored LLR value 301 is added with values of three variable nodes 311 to 313, and a variable node message that will be transferred from the variable nodes 311 to 313 to the check node 321 is calculated based on the adding result. The calculated variable node message is transferred to the check node 321 through the edge 331.

The transferred variable node message is used to calculate a check node message which is transferred from the check node 321 to the variable nodes 311 to 313. The variable nodes 311 to 313 and the check node 321 are updated through exchanging the variable node messages and the check node message. The update process is repeated predetermined times or until it reaches a predetermined state. In general, as the update process is repeated more, the performance of a LPCD decoding apparatus becomes better. However, the processing speed is reduced.

As shown in FIG. 4, a variable node update process according to the related art includes a process of calculating a variable node message using an inputted LLR value 301 and three variable node values 311 and 313. That is, a variable node message of a variable node 311 to calculate is calculated using remaining values of two variable nodes 312 and 313 and a LLR value 301.

In case of a LDPC decoding apparatus using a parallel processing scheme according to the related art, the LDPC decoding apparatus needs a memory for storing thirty LLR values, a variable node update device for updating thirty variable node messages, and a check node update device for updating fifteen check node messages. Also, the LDPC decoding apparatus needs a memory for storing ninety variable node messages corresponding to the number of edges 331, a memory for storing ninety check node messages, and a device for randomly connecting the variable node messages and the check node messages. Here, the variable node update method and the check node update method may be one of message update methods according to the related art.

Therefore, the LDPC decoding apparatus according to the related art needs a huge memory for storing each of the variable nodes and the check nodes and needs to calculate all ninety variable node messages and check node messages. Accordingly, the LDPC decoding apparatus according to the related art cannot perform decoding at the optimal speed due to complexity of randomly connection of variable nodes and check nodes.

FIG. 5 is a diagram illustrating an apparatus for decoding low density parity code (LDPC) using a prototype parity matrix in accordance with an embodiment of the present invention.

As shown in FIG. 5, the apparatus for decoding LDPC according to the present embodiment includes a bit input unit 410, a check matrix processing unit 420, and a bit processing unit 430. The check matrix processing unit 420 includes a variable node processor 421 and a check node processor 422. The bit processing unit 430 includes a variable node sum calculator 431, a bit determiner 432, and a bit output unit 433.

The bit input unit 410 receives a log likelihood ratio for the input bit.

The check matrix processing unit 420 sequentially partial-parallel processes the parity check matrix for the inputted log likelihood ratio using a prototype parity check matrix. Here, the prototype parity check matrix is a parity check matrix related with one a row by a sub-matrix among parity check matrices.

The bit processing unit 430 determines a bit-level from the partial-parallel processed parity check matrix, restores an input bit based on the bit-level, and outputs the restored input bit.

Hereinafter, the constituent elements of the apparatus for decoding LDPC according to the present embodiment will be described in detail.

The bit input unit 410 sequentially receives LLR values for input bits from an LDPC encoding apparatus and transfers the inputted LLR values to the variable node processor 421 at a given time. The process of transferring the LLR values may be differently performed at parity check matrices.

The variable node processor 421 calculates a variable node message by calculating the sum of the LLR value from the bit input unit 410 and the variable node values, and transfers the calculated variable node message to the check node processor 422. The variable node processor 421 receives a check node message from the check node processor 422. That is, the variable node processor 421 updates a variable node through exchanging the messages.

The check node processor 422 calculates a check node message by applying the transferred variable node message from the variable node processor 421 to a check node calculating process. The check node processor 422 performs a parallel processing method for increasing decoding speed or performs a serial or partial-parallel processing method for reducing decoding complexity. The check node processor 422 transfers the calculated check node message to the variable node processor 421.

The variable node processor 421 cyclic-shifts the LLR value and the variable node values by a sub-matrix and performs partial parallel processing on the parity check matrix in sequence.

The variable node processor 421 repeats calculating the sum of the cyclic-shifted variable nodes and LLR value. Here, the variable node processor 421 updates necessary variable nodes required to calculate a variable node message using the transferred check node message from the check node processor 422. The variable node processor 421 calculates a variable node message using the updated variable node value. After the variable node processor 421 and the check node processor 422 perform the LDPC decoding operation as many as predetermined times set by a user, the variable node sum calculator 431 calculates a variable node sum of a LLR value and an edge value of each variable node, and transfers the sum to the bit determiner 432.

The bit determiner 432 restores an input bit by determining a bit level as 0 or 1 corresponding to the calculated variable node sum from the variable node sum calculator 431.

The bit output unit 433 receives the restored input bit from the bit determiner 432 at a given time and sequentially outputs the input bit. Here, the input bit output process may be differently performed according to a parity check matrix.

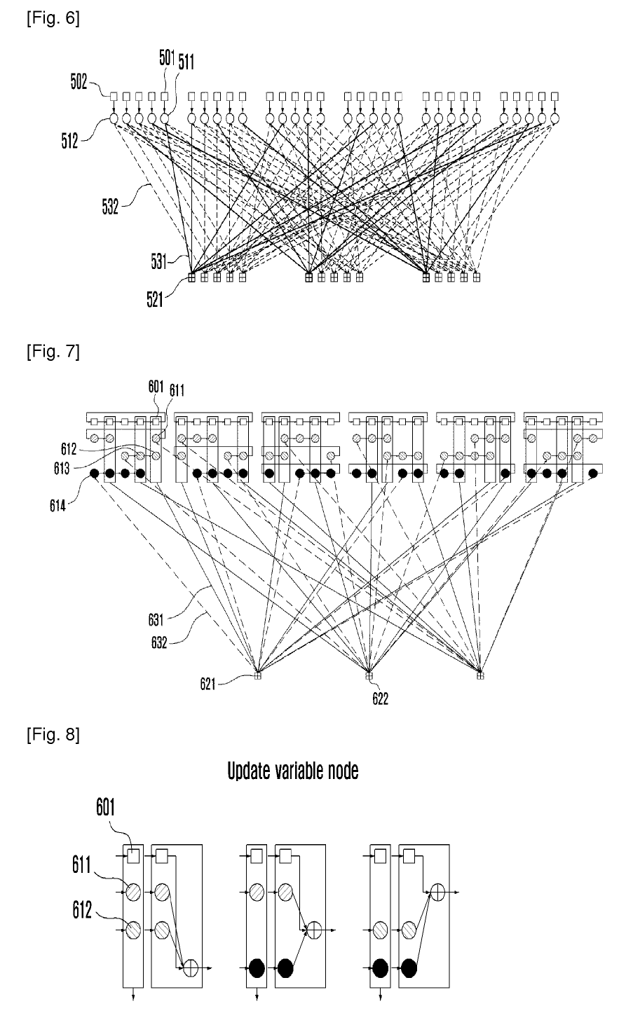

FIG. 6 is a diagram illustrating an edge connected to a first check node among edges connecting variable nodes and check nodes shown in FIG. 2.

As shown in FIG. 6, edges 531 connected to the first check node are shown as a thick solid line. On the contrary, other edges 532 connected to second to fifth check nodes are shown as dotted lines.

The variable node processor 421 calculates a variable node message by processing a LLR value 501 and a variable node value 511. The variable node message is transferred through the edge 531 shown as the thick solid line.

The variable node processor 421 may calculate a next variable node message by cyclic shifting the LLR value 502 and the variable node value 512. That is, the variable node processor 421 can calculate the edges 532 through the cyclic shifting operation with the edge 531. Such a cyclic shift process will be described in detail.

FIGS. 7 and 8 are diagrams illustrating a factor graph of a parity check matrix in accordance with an embodiment of the present invention.

The factor graph according to the present embodiment shown in FIG. 7 include eighteen edges 631 unlike the factor graph according to the related art shown in FIG. 3 including ninety edges 331 between the variable nodes 311 to 313 and the check node 321.

The fact graph according to the present embodiment includes six edges 631, shown as a solid line, connected to each check node to transfer a variable node message. Also, the fact graph according to the present embodiment includes six edges 632, shown as dotted lines, connected to each check node to transfer a check node message. As shown, the number of edges 631 is reduced about five times, from ninety to eighteen, and the number of check nodes 621 is reduced from fifteen to three.

The check node processor 422 performs a normal check node processing operation.

The variable node processor 421 cyclic shifts variable nodes 611 and 612 and a LLR value 601 by a sub-matrix at every processing time, and calculates a variable node message to be transferred from the variable nodes 611 and 612 to the check node 621. That is, the variable node processor 421 performs a variable node update process by calculating the sum of the LLR value 601 and remaining variable node values 611 and 613 excepting a variable node to calculate.

For example, the variable node processor 421 calculates a variable node message by performing predetermined calculation only for columns corresponding to the variable node values 611 and 612 and the LLR value 601. The variable node processor 421 transfers the calculated variable node message to the check node 621 through the edge 631.

Then, the variable node processor 421 calculates a next variable node message by performing calculation only for the column through cyclic shifting an adjacent variable node value 613 and a check node message transferred from the check node 622 to the variable nodes 611 and 612.

The check node processor 422 calculates a variable node message by calculating a variable node message to be transferred to the check node 621 and transfers the calculated variable node message to the variable node 614 through the edge 632.

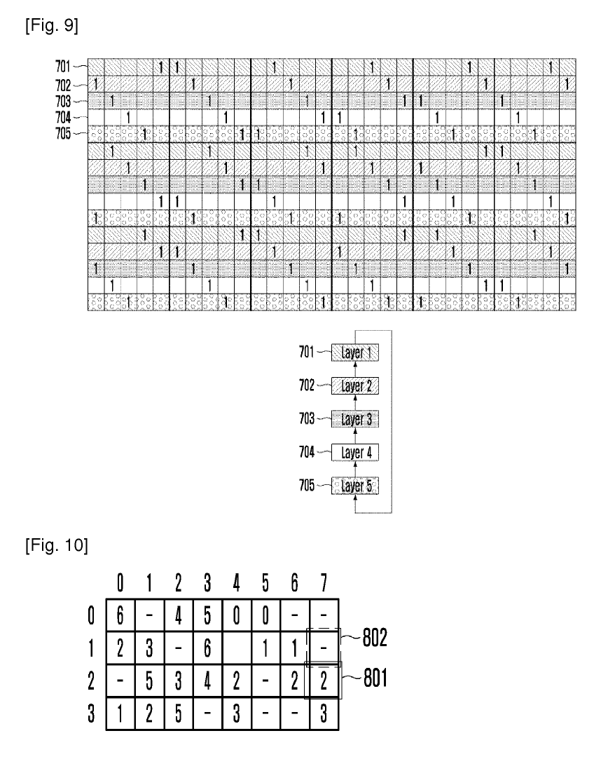

FIG. 9 is a diagram illustrating a method for sequentially processing a parity check matrix of FIG. 1 using a prototype parity check matrix in accordance with an embodiment of the present invention.

As shown in FIG. 9, the parity check matrix of FIG. 1 includes thirty columns and fifteen rows. As described above, the variable node processor 421 sequentially performs the variable node update process at each of layers 701 to 705. The variable node update process may refer to a variable node message calculating process.

For example, the variable node processor 421 performs the variable node update process as many as the number of “1”s of the first column 701 shown in FIG. 9. Then, the variable node processor 421 performs a cyclic shifting process and performs the same variable node update process for the second column 702. The variable node processor 421 may perform the same variable node update process for the third to fifth columns.

The variable node processor 421 performs the cyclic shift process by each sub-matrix at every processing time, and the variable node update process is repeated in order of each row 701 to 705.

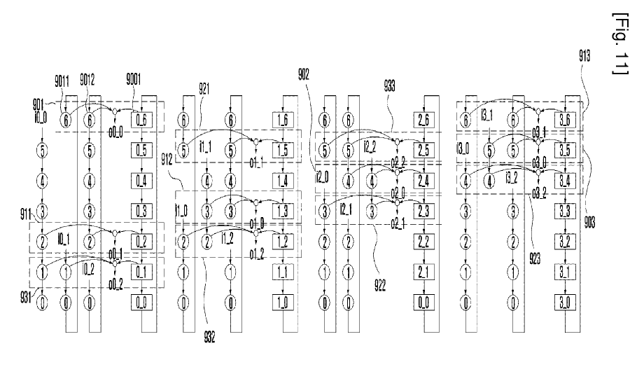

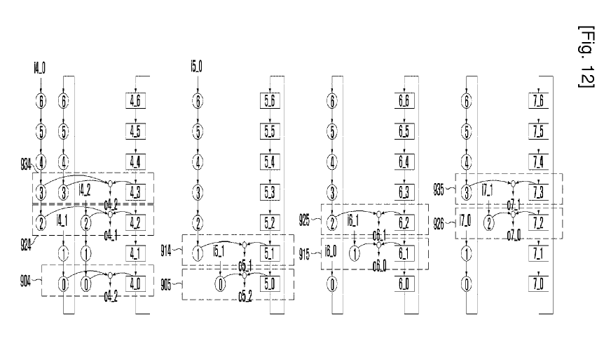

FIG. 10 is a diagram illustrating a parity check matrix of an irregular Quasi Cyclic Low Density Parity Check (QC-LDPC) code where the present invention is applied to.

As shown in FIG. 10, in the parity check matrix of the irregular QC-LDPC code, squares 801 and 802 denote 7×7 unitary matrices (sub-matrix) and a value inside thereof denotes the number of columns cyclically shifted to the right. For example, the square 801 with a value of “2” means a sub matrix cyclic-shifted to the right as many as 2 columns. The square 801 with a value of “−” means a 0 matrix where all elements are “0”.

Therefore, the parity check matrix of the irregular QC-LDPC code shown in FIG. 10 is constituted of 7×7 sub-matrices in four rows and eight columns. That is, the parity check matrix of the irregular QC-LDPC code is constituted of twenty eight rows and fifty six columns. A value obtained by adding “1” to each row is inconstant. For example, the value may be 5 or 6. A value obtained by adding “1” to each column is also inconstant. For example, the value may be 2 or 3.

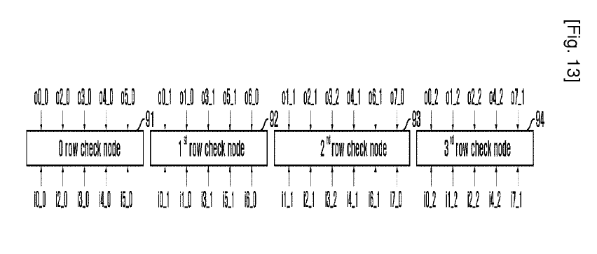

FIGS. 11 to 13 are diagrams illustrating a method for partial parallel processing a parity check matrix using a prototype parity check matrix in accordance with an embodiment of the present invention.

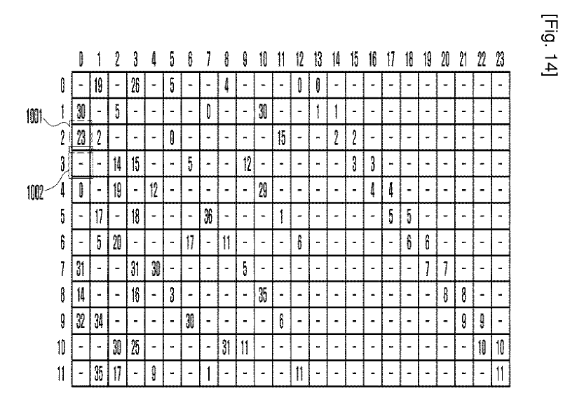

As shown in FIGS. 11 and 12, twenty one edges are required between variable nodes and check nodes, which is the same number of sub-matrices in the parity check matrix of FIG. 10. In the diagram, variable nodes are not directly connected to the check nodes. Each of the edges is required to connect a variable node and a check node corresponding to the prototype parity check matrix.

The variable node processor 421 calculates a variable node message by calculating the sum of a LLR value 9001 and a variable node value 9011 for each variable node corresponding to the prototype parity check matrix of the parity check matrix shown in FIG. 10. As shown in FIG. 11, the variable node messages are o0_0, o0_1, o0_2, o1_1, . . . , o7_1, and o7_0. The variable node processor 421 transfers the calculated variable node messages to 0^{th} column to third column check nodes 91 to 94. The variable node processor 421 cyclic-shifts the LLR value 9001 and the variable node value 9012 by sub-matrix.

For example, the variable node processor 421 calculates a variable node message o0_0 for a sub-matrix cyclically shifted six times, which correspond to the first row and the first column of the parity check matrix, by calculating the sum of corresponding variable node values 9011 and 9012 and the LLR value 9001. The variable node processor 421 calculates variable node messages o0_0, o0_1, o0_2, o1_1, . . . , o7_1, and o7_0 by performing twenty one times of the same variable node message calculating processes 901 to 905, 911 to 915, 921 to 926, and 931 to 935, which correspond to a sub-matrix value of the parity check matrix. The variable node processor 421 repeatedly updates a variable node by cyclic-shifting the variable node value 9012 and the LLR value 9001 by a sub-matrix.

As shown in FIG. 13, the check node processor 422 stores the calculated variable node messages o0_0, o0_1, o0_2, o1_1, o7_1, and o7_0 in 0^{th} to 3^{rd} check nodes 91 to 94.

The check node processor 422 calculates check node messages i0_0, i2_0, i3_0, i4_0, and i5_0 by applying the stored 0^{th} column variable node messages o0_0, o2_0, o3_0, o4_0, o5_0 to the check node calculating process. Then, the variable node processor 421 transfers the calculated check node messages i0_0, i2_0, i3_0, i4_0, and i5_0 to the variable node processor 421. The variable node processor stores the check node messages i0_0, i2_0, i3_0, i4_0, i5_0 in corresponding variable nodes. The same process is performed for 1^{st} to 3^{rd} row check nodes as check node calculation.

FIG. 14 is a diagram illustrating a parity check matrix of an irregular QC-LDPC code where the present invention is applied.

As shown in FIG. 14, in the parity check matrix of the irregular QC-LDPC code, squares 1001 and 1002 denote 38×38 unitary matrices (sub-matrix) and a value inside thereof denotes the number of columns cyclically shifted to the right. For example, the square 1101 has a value of “23”. That is, the square 1101 means a sub-matrix cyclic shifted to the right as many as 23 columns. The square 1002 has a value of “−”. The square 1002 means a 0 matrix where all elements are “0”.

As shown in FIG. 14, the parity check matrix of the irregular QC-LDPC code is constituted of 38×38 sub-matrixes in twelve rows and twenty four columns. That is, the parity check matrix of the irregular QC-LDPC code is constituted of 456 rows and 912 columns. Also, 73 edges are required for connecting variable nodes and check node, which is the number of sum-matrices excepts 0 matrices such as the square 1002 having a value of “−” if the method for decoding the LDPC code according to the present embodiment is applied.

In the present embodiment, the variable node operation and the check node processing operation can be differently performed according to whether a fast decoding speed is required or a low complexity is required. That is, the variable node processing operation and the check node processing operation are performed through parallel processing if the fast decoding speed is required. If the low complexity is required, the variable node processing operation and the check node processing operations are performed through one of serial processing or partial parallel processing.

For example, if it is required to perform the variable node processing operation and the check node processing operation for a sub-matrix with 73 edges at a high decoding speed, the variable node processor 421 performs the variable node processing operation in parallel. Such a variable node processing operation includes 4 variable node processing operations for a 6 degree variable node, 9 variable node processing operation for a 3 degree variable node, and 11 variable node processing operations for a 2 degree variable node. Also, the check node processing operation includes 11 check node processing operations for a 6 degree check node, and one check node processing operation for a 7 degree check node.

If it is required to perform the variable node processing operation and the check node processing operation for a sub-matrix having 73 edges, which is shown in FIG. 14, with low complexity, the variable node processor 421 performs the variable node processing operation through partial-parallel processing. In this case, the complexity may be lowered although the processing speed becomes slower. It is useful if the low complexity is required and the high speed decoding is not required.

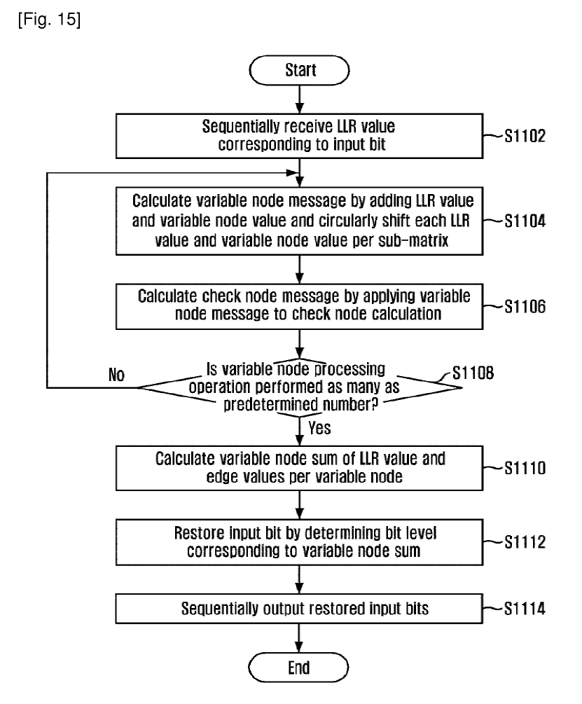

FIG. 15 is a flowchart illustrating a method for decoding a LDPC code using a prototype matrix in accordance with an embodiment of the present invention.

At step S1102, the bit input unit 410 sequentially receives LLR values corresponding to input bits from the LDPC decoding apparatus.

At step S1104, the variable node processor 421 calculates a variable node message by calculating the sum of the received LLR value and the variable node values from the bit input unit 410 and cyclic-shifts each of the LLR values and the variable nodes by a sub-matrix at every processing times. That is, the variable node processor 421 performs a variable node update process.

Then, the check node processor 422 calculates a check node message by applying the variable node message calculated from the variable node processor 421 to the check node calculating operation at step S1106. Here, the check node processor 422 performs parallel processing for increasing a decoding speed or performs serial processing or partial parallel processing for lowering decoding complexity. That is, the check node processor 422 performs a check node update operation.

The variable node processor 421 determines whether the steps S1104 and S1106 are repeated as many as predetermined times at step S1108.

If the steps S1104 and S1106 are repeated as many as the predetermined times at step S1108, the variable node sum calculator 431 calculates a variable node sum of a LLR value and an edge value of each variable node at step S1110. On the contrary, if the steps S1104 and S1106 are not repeated as many as the predetermined times at step S1108, the steps S1104 and S1106 are performed again.

Then, the bit determiner 432 restores an input bit by determining a bit level corresponding to the variable node sum calculated from the variable node sum calculator 431 as “0” or “1” at step S1112.

At step S1114, the bit output unit 433 sequentially outputs the input bits “0” or “1”, calculated from the bit determiner 432. Here, the restored input bits may be outputted in various methods according to a parity check matrix.

The above described method according to the present invention can be embodied as a program and stored on a computer readable recording medium. The computer readable recording medium is any data storage device that can store data which can be thereafter read by the computer system. The computer readable recording medium includes a read-only memory (ROM), a random-access memory (RAM), a CD-ROM, a floppy disk, a hard disk and an optical magnetic disk.

The present application contains subject matter related to Korean Patent Application No. 2007-0129185, filed in the Korean Intellectual Property Office on Dec. 12, 2007, the entire contents of which is incorporated herein by reference.

While the present invention has been described with respect to the specific embodiments, it will be apparent to those skilled in the art that various changes and modifications may be made without departing from the spirit and scope of the invention as defined in the following claims.

1. An apparatus for decoding a low density parity check (LDPC) code using a prototype parity check matrix, comprising:
a bit input means for receiving a log likelihood ratio (LLR) value for an input bit;
a check matrix processing means for sequentially processing a parity check matrix for the received LLR value using a prototype parity check matrix through partial-parallel processing; and
a bit processing means for restoring the input bit by determining a bit level from the partial-parallel processed parity check matrix value.

2. The apparatus of claim 1, wherein the check matrix processing means cyclic shifts the received LLR value and variable nodes of the prototype parity check matrix by a sub-matrix for sequentially processing the parity check matrix through partial-parallel processing.

3. The apparatus of claim 2, wherein the check matrix processing means includes:
a variable node processing unit for calculating a variable node message by cyclic-shifting the received LLR value and the variable nodes of the prototype parity check matrix by a sub-matrix; and
a check node processing unit for calculating a check node message through performing a check node calculating operation on the calculated variable node message by a sub-matrix.

4. The apparatus of claim 3, wherein the variable node processing means updates variable nodes necessary for calculating the variable node message using the received check node message.

5. The apparatus of claim 4, wherein the variable node processing means includes a memory for storing variable nodes necessary for calculating the variable node message.

6. The apparatus of claim 3, wherein the variable node processing means performs parallel processing to calculate the variable node message if a fast decoding speed is required.

7. The apparatus of claim 3, wherein the variable node processing means performs one of serial processing and partial-parallel processing to calculate the variable node message if low complexity is required.

8. The apparatus of claim 1, wherein the bit processing means includes:
a variable node sum calculating unit for calculating a variable node sum of an edge value of each variable node of the partial-parallel processed parity check matrix and the received LLR value;
a bit determining unit for restoring the input bit by determining a bit level corresponding to the calculated variable node sum; and
a bit output unit for outputting the restored input bit.

9. A method for decoding a low density parity check (LDPC) code, comprising:
receiving a log likelihood ratio (LLR) value for an input bit;
sequentially processing a parity check matrix for the received LLR value using a prototype parity check matrix through partial-parallel processing; and
restoring the input bit by determining a bit level from the partial-parallel processed parity check matrix value.

10. The method of claim 9, wherein in said sequentially processing a parity check matrix, the received LLR value and variable nodes of the prototype parity check matrix are cyclic-shifted by a sub-matrix for sequentially processing the parity check matrix through partial-parallel processing.

11. The method of claim 10, wherein said sequentially processing a parity check matrix includes:
calculating a variable node message by cyclic-shifting the received LLR value and the variable nodes of the prototype parity check matrix by a sub-matrix; and
calculating a check node message through performing a check node calculating operation on the calculated variable node message by a sub-matrix.

12. The method of claim 11, wherein in said calculating a variable node message, variable nodes necessary for calculating the variable node message are updated using the received check node message.

13. The method of claim 11, wherein in said calculating a variable node message, parallel processing is performed to calculate the variable node message if a fast decoding speed is required.

14. The method of claim 11, wherein in said calculating a variable node message, one of serial processing and partial-parallel processing is performed to calculate the variable node message if low complexity is required.

15. The method of claim 9, wherein said restoring the input bit includes:
calculating a variable node sum of an edge value of each variable node of the partial-parallel processed parity check matrix and the received LLR value;
restoring the input bit by determining a bit level corresponding to the calculated variable node sum; and
outputting the restored input bit.
